(19) United States
(12) Patent Application Publication
(10) Pub. No.: US 2010/0282285 A1
(43) Pub. Date: Nov. 11, 2010

(54) EXTRUSION PROCESS FOR PREPARING IMPROVED THERMOELECTRIC MATERIALS

(75) Inventors: Klaus Kuehling, Ellerstadt (DE); Hans-Josef Sterzel, Dannstadt-Schauernheim (DE); Haass Frank, Erzhausen (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASE SE, LUDWIGSHAFEN (DE)

(21) Appl. No.: 12/810,931

(22) PCT Filed: Dec. 19, 2008
(86) PCT No.: PCT/EP08/68085

§ 371 Date: Jun. 28, 2010

(30) Foreign Application Priority Data
Dec. 28, 2007 (EP) 07150470.8

(51) Int. Cl. H01L 35/34

(52) U.S. Cl. 136/201

(57) ABSTRACT

For a process for reducing the thermal conductivity and for increasing the thermoelectric efficiency of thermoelectric materials based on lead chalcogenides or skutterudites, the thermoelectric materials are extruded at a temperature below their melting point and a pressure in the range from 300 to 1 000 MPa.

The present invention relates to processes for reducing the thermal conductivity and for increasing the thermoelectric efficiency of thermoelectric materials, for example based on lead chalcogenides, and to thermoelectric materials obtained by this process. More particularly, lead tellurides or skutterudites with improved thermoelectric properties are to be provided, as are doped lead tellurides comprising lead and tellurium and at least one or two further dopants, as are thermoelectric generators and Peltier arrangements comprising them.

Thermoelectric generators and Peltier arrangements as such have been known for some time. p- and n-doped semiconductors which are heated on one side and cooled on the other side transport electrical charges through an external circuit, and electrical work can be performed by a load in the circuit. The efficiency of conversion of heat to electrical energy achieved in this process is limited thermodynamically by the Carnot efficiency. Thus, at a temperature of 1000 K on the hot side and 400 K on the “cold” side, an efficiency of (1000−400):1000=60% would be possible. However, only efficiencies below 10% have been achieved to date.

On the other hand, when a direct current is applied to such an arrangement, heat is transported from one side to the other side. Such a Peltier arrangement works as a heat pump and is therefore suitable for cooling apparatus parts, vehicles or buildings. Heating via the Peltier principle is also more favorable than conventional heating, because more heat is always transported than corresponds to the energy equivalent supplied.

At present, thermoelectric generators are used inter alia in space probes for generating direct currents, for cathodic corrosion protection of pipelines, for energy supply to light buoys and radio buoys, for operating radios and television sets. The advantages of thermoelectric generators lie in their extreme reliability. For instance, they work irrespective of atmospheric conditions such as atmospheric moisture; there is no fault-prone mass transfer, but rather only charge transfer; it is possible to use any fuels from hydrogen through natural gas, gasoline, kerosene, diesel fuel up to biologically obtained fuels such as rapeseed oil methyl ester.

Thermoelectric energy conversion thus fits extremely flexibly into future requirements such as hydrogen economy or energy generation from renewable energies.

A particularly attractive application would be the use for conversion to electrical energy in electrically operated vehicles. There is no need for this purpose to undertake any change in the existing network of gas stations. However, efficiencies greater than 10% are generally required for such an application.

The conversion of solar energy directly to electrical energy is also very attractive. Concentrators such as parabolic troughs can concentrate solar energy to thermoelectric generators, which generates electrical energy.

However, higher efficiencies are also needed for utilization as a heat pump.

Thermoelectrically active materials are rated essentially with reference to their efficiency. A characteristic of thermoelectric materials in this regard is what is known as the Z factor (figure of merit):

$$Z = \frac{{S}^{2} \cdot σ}{κ}$$

with the Seebeck coefficient S, the electrical conductivity a and the thermal conductivity κ. Preference is given to thermoelectric materials which have a very low thermal conductivity, a very high electrical conductivity and a very large Seebeck coefficient, so that the figure of merit assumes a very high value.

The product S²σ is referred to as the power factor and serves in particular to compare similar thermoelectric materials.

In addition, the dimensionless product Z•T (thermoelectric efficiency) is often reported for general comparative purposes. Thermoelectric materials known to date have maximum values of Z•T of about 1 at an optimal temperature. Beyond this optimal temperature, the values of Z•T are often significantly lower than 1.

A more precise analysis shows that the efficiency η is calculated from

$$η = \frac{{T}_{high} - {T}_{low}}{{T}_{high}} \frac{M - 1}{M + \frac{{T}_{low}}{{T}_{high}}}$$

$$where$$

$$M = {[ 1 + \frac{Z}{2} ( {T}_{high} + {T}_{low} ) ]}^{\frac{1}{2}}$$

(see also Mat. Sci. and Eng. B29 (1995) 228).

The aim is thus to provide a thermoelectric material having a very high value of Z and/or Z T and a high realizable temperature differential. From the point of view of solid state physics, many problems have to be overcome here:

A high σ requires a high electron mobility in the material, i.e. electrons (or holes in p-conducting materials) must not be bound strongly to the atomic cores. Materials having high electrical conductivity a usually simultaneously have a high thermal conductivity (Wiedemann-Franz law), which does not allow Z to be influenced favorably. Materials used at present, such as Bi₂Te₃, already constitute compromises. For instance, the electrical conductivity is lowered by alloying to a lesser extent than the thermal conductivity. Preference is therefore given to using alloys, for example (Bi₂Te₃)₉₀(Sb₂Te₃)₅(Sb₂Se₃)₅ or Bi₁₂Sb₂₃Te₆₅.

For thermoelectric materials having high efficiency, still further boundary conditions preferably have to be fulfilled. In particular, they have to be sufficiently thermally stable in order to be able to work under operating conditions for years without significant loss of efficiency. This requires a phase which is thermally stable at high temperatures per se, a stable phase composition, and a negligible diffusion of alloy constituents into the adjoining contact materials.

WO 01/17034 describes the preparation of thermoelectric materials based on two or more elements from the group of Bi, Sb, Te and Se by extrusion of pulverulent or compact alloy powders. The hot extrusion is intended to reduce internal microscopic defects and hence to afford good thermoelectric and mechanical properties.

F. Belanger et al. describe, in Advances In Powder Metallurgy & Particulate Materials—2001, Proceedings of the 2001 International Conference on Powder Metallurgy & Particulate Materials, May 13 to 17, 2001, New Orleans, pages 9-88 to 9-98, the improvement in the thermoelectric properties of bismuth telluride alloys by enhancing the microstructure by extrusion.

The preparation of thermoelectric elements by extrusion is described in general form in U.S. Pat. No. 3,220,199. As well as other materials, lead tellurides are also mentioned as material. However, specific extrusion conditions are specified only for bismuth tellurides. A flux is used, and the bodies produced have a cross section of at least 20 mm².

Hydrostatic extrusion of thermoelectric materials is described in general terms in U.S. Pat. No. 4,161,111. Lead telluride is also discussed there.

For the extrusion processes, advantageous thermoelectric properties are described only in very general form. No such properties are specified for lead tellurides.

It is an object of the present invention to provide a process for reducing the thermal conductivity and for increasing the thermoelectric efficiency of thermoelectric materials, for example based on lead chalcogenides, especially lead tellurides or skutterudites.

The object is achieved in accordance with the invention by extruding the thermoelectric materials at a temperature below their melting point and a pressure in the range from 300 to 1000 MPa.

It has been found in accordance with the invention that the extrusion of the lead chalcogenides or skutterudites at a temperature below their melting point and a pressure in the range from 300 to 1000 MPa makes it possible to obtain homogeneous materials which, with a virtually unchanged Seebeck coefficient, exhibit a significantly reduced thermal conductivity and a considerably enhanced thermoelectric efficiency. The electrical conductivity is reduced only slightly at low temperatures.

The invention also relates to thermoelectric materials obtainable by the process, and to the use of extruders for reducing the thermal conductivity and for increasing the thermoelectric efficiency of thermoelectric materials based on lead chalcogenides or skutterudites.

The process according to the invention can be carried out, for example, as described in WO 01/17034. Especially suitable processes are described, for example, in J. Appl. Phys. Vol. 92, No. 5, September 2002, pages 2610 to 2613, the reference by F. Belanger cited at the outset, J.-M. Simard, 22nd International Conference on Thermoelectrics (2003), pages 13 to 18. Alternative processes are described in U.S. Pat. No. 3,220,199 or U.S. Pat. No. 4,161,111.

The starting materials are lead chalcogenides such as PbS, PbSe or PbTe. Preference is given to using PbTe. The lead chalcogenides, especially lead telluride, can be used in n- and p-doping. Suitable dopants in the process for preparing the starting materials are described, for example, in WO 2007/104601.

According to the invention, preference is given to working without fluxes. Preference is given to working with isostatic extrusion.

Dopants are, for example, selected from the group of the elements Li, Na, K, Rb, Cs, Be, Mg, Ca, Sr, Ba, Al, Ga, In, Tl, Si, Ge, Sn, As, Sb, Bi, S, Se, Br, I, Sc, Y, La, Ti, Zr, Hf, V, Nb, Ta, Cr, Mo, W, Mn, Re, Fe, Ru, Os, Co, Rh, Ir, Ni, Pd, Pt, Cu, Ag, Au, Zn, Cd, Hg, Ce, Pr, Nd, Sm, Eu, Gd, Tb, Dy, Ho, Er, Tm, Yb, Lu, preferably selected from the group of the elements

Al, In, Si, Ge, Sn, Sb, Bi, Se, Ti, Zr, Hf, Nb, Ta, Cu, Ag, Au,

especially selected from the group of the elements

In, Ge, Ti, Zr, Hf, Nb, Ta, Cu, Ag, or selected from Ti, Zr, Ag, Hf, Cu, Ge, Nb, Ta.

It is possible that, proceeding from PbTe, in a formal sense,
Pb or Te are replaced by one or at least two dopants or
one or at least two dopants are added to PbTe or
one or at least two dopants assume some of the Pb or Te positions,
   in each case changing the ratio of Pb:Te—proceeding from 1:1.

For the inventive materials of the series, typically, Seebeck coefficients in the range of generally from 150 to 400 μV/K are achieved for p-conductors, and generally of from −150 to −400 μV/K for n-conductors. The power factors achieved at room temperature are generally at least 20 μW/K²·cm.

The selection of specific suitable dopants and chemical additives for adjustment of charge carrier concentration and charge carrier mobility is known to those skilled in the art. To this end, for example, tellurium can be replaced in each case completely or partly by selenium and/or partly by sulfur.

The use temperatures of the lead tellurides in thermoelectric materials are typically from 250 to 600° C. However, there are also lead telluride materials which can also be used below 250° C., for example at room temperature.

Skutterudites prepared in accordance with the invention correspond preferably to the structures CoSb₃, Co_{0.9}Sn_{0.1}Sb₃, LaCoSb₃, GdCoSb₃ or SeCoSb₃.

The thermoelectric material used can be prepared by melt synthesis or mixing of element or alloy powders.

The thermoelectrically active materials are usually synthesized from the melt, by mechanical alloying or by similar processes. Subsequently, another processing step is frequently necessary, which further compacts the materials. A conventional step for this purpose is that of grinding and subsequent (hot)pressing. This is intended not just to further compact and consolidate the material itself; the new orientation of the grains and morphological influences allow the thermal conductivity, which should be at a minimum, and the electrical conductivity, which should be at a maximum, to be favorably influenced, while it is barely possible to vary the third important parameter, the Seebeck coefficient, in this manner.

The materials used in accordance with the invention for the extrusion are generally prepared by reactive grinding or preferably by co-melting and reaction of mixtures of the particular element constituents or alloys thereof. In general, a reaction time for the reactive grinding or preferably co-melting of at least one hour has been found to be advantageous.

The co-melting and reaction are effected preferably over a period of at least 1 hour, more preferably at least 6 hours, especially at least 10 hours. The melting process can be effected with or without mixing of the starting mixture. When the starting mixture is mixed, suitable apparatus for this purpose is especially a rotary or tilting oven, in order to ensure the homogeneity of the mixture.

If no mixing is undertaken, generally longer melting times are required in order to obtain a homogeneous material. If mixing is undertaken, the homogeneity in the mixture is already obtained at an earlier stage.

Without additional mixing of the starting mixtures, the melting time is generally from 2 to 50 hours, especially from 30 to 50 hours.

The co-melting is effected generally at a temperature at which at least one constituent of the mixture has already melted and the material is already in the molten state. In general, the melting temperature is at least 800° C., preferably at least 950° C. Typically, the melting temperature is within a temperature range of from 800 to 1100° C., preferably from 950 to 1050° C.

After the molten mixture has been cooled, it is advantageous to heat treat the material at a temperature of generally at least 100° C., preferably at least 200° C., lower than the melting point of the resulting semiconductor material. Typically, the temperature is from 450 to 750° C., preferably from 550 to 700° C.

The heat treatment is carried out over a period of preferably at least 1 hour, more preferably at least 2 hours, especially at least 4 hours. Typically, the heat treatment time is from 1 to 8 hours, preferably from 6 to 8 hours. In one embodiment of the present invention, the heat treatment is carried out at a temperature which is from 100 to 500° C. lower than the melting point of the resulting semiconductor material. A preferred temperature range is from 150 to 350° C. lower than the melting point of the resulting semiconductor material.

The thermoelectric materials to be extruded in accordance with the invention are prepared generally in an evacuated and closed quartz tube. Mixing of the components involved can be ensured by using a rotatable and/or tiltable oven. On completion of the conversion, the oven is cooled. Thereafter, the quartz tube is removed from the oven and the semiconductor material present in the form of blocks is comminuted.

Instead of a quartz tube, it is also possible to use tubes or ampoules made of other materials inert toward the semiconductor material, for example made of tantalum.

Instead of tubes or ampoules, it is also possible to use other vessels of suitable shape. It is also possible to use other materials, for example graphite, as the vessel material, provided that they are inert toward the semiconductor material.

In one embodiment of the present invention, the cooled material can be ground at a suitable temperature in a wet or dry state or in another suitable manner, so as to obtain the inventive semiconductor material in typical particle sizes of less than 10 μm. The ground inventive material is then hot-extruded.

The hot extrusion has to be effected at temperatures significantly above room temperature in order that the material receives adequate flow properties and can be extruded. For the lead chalcogenides used in accordance with the invention, especially lead tellurides, the temperature in the extrusion is preferably from 430 to 630° C., especially from 500 to 560° C. The pressure is typically from 300 to 1000 MPa, more preferably from 500 to 700 MPa.

The extrusion can be carried out as a hot extrusion, hydrostatic extrusion or equal channel extrusion.

Before the extrusion and after the alloy preparation and comminution, it is optionally also possible to carry out a compaction and optionally a heat treatment, as described, for example, in WO 01/17034 on pages 11 and 12.

The extrusion treatment may be the direct or indirect type. In both cases, the alloy is filled into the extrusion cylinder. The heating can be effected directly in the extrusion cylinder or in a separate oven. In the course of heating, contact with the surrounding atmosphere should, however, be prevented. The extrusion is preferably carried out under protective gas, preferably with an inert gas or reducing gas or a mixture thereof. Preference is given to using a gas selected from argon, nitrogen and mixtures thereof. The extrusion itself can preferably be carried out as described in WO 01/17034 on pages 12 to 14. In the extrusion, in a continuous process, compaction leading to values of preferably more than 99% of the theoretical density is achieved. Processing in the melt leads typically only to a density in the region of about 90% of the theoretical density.

The extrusion may be followed by a further heat treatment in order to eliminate stresses in the material.

The extrusion can lead to any desired cross-sectional geometries of the extrudate, for example based on the diameter and the shape of the cross section, which allows the further processing to a thermoelectric module to be simplified considerably. Rods or strands produced by extrusion can, for example, be sawn up and polished, which makes possible the production of any desired components.

Alternatively to the customary extrusion, hydrostatic extrusion can also be effected, in which pressure is exerted on the material to be extruded from several sides by means of a liquid. A suitable process for hydrostatic extrusion is described, for example, in U.S. Pat. No. 4,161,111.

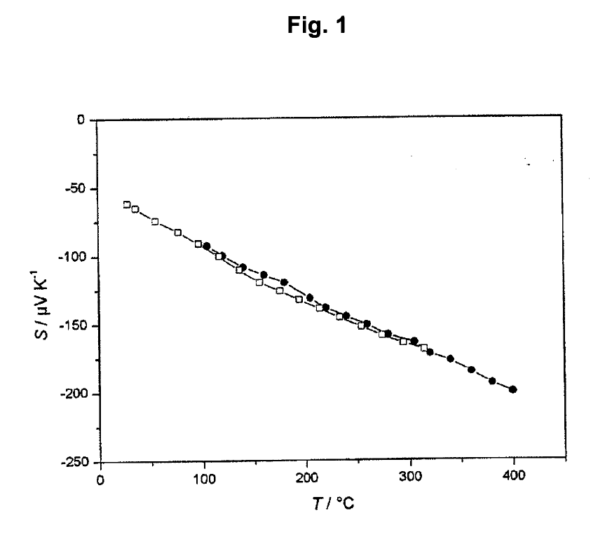

In addition, equal channel extrusion can be carried out, in which the extrudate is pushed or forced around a bend or corner during the extrusion. A suitable process is described, for example, in Acta Materialia 52 (2004), pages 49 to 55. For the production scheme, reference may be made especially to FIG. 1 on page 50.

The process according to the invention allows, through hot extrusion, the production of a compact, homogeneous material, wherein the density can be increased to values of more than 99%, for example up to 99.9%, of the theoretical density.

With regard to a continuous process and module construction too, the extrudate is outstandingly processible, for example by sawing.

The Seebeck coefficient is not altered significantly, i.e. the underlying chemical composition and the phase ratios of the material are not altered, but rather merely the morphology, i.e. the particle size distribution and the particle boundaries.

The electrical conductivity is reduced slightly, but this is of no consequence except at low temperatures.

The thermal conductivity is reduced significantly over the entire temperature range. Without being bound to a theory, it is assumed that this reduction is enabled by an at least partial decoupling of lattice content and electronic content of the thermal conductivity, which would not be possible through a purely chemical modification of the material alone.

The thermal conductivity, overall, also has the greatest influence on the observed rise in the thermoelectric efficiency.

The invention also relates to a thermoelectric material which is obtainable by the process according to the invention.

The present invention further provides for the use of the above-described semiconductor material and of the semiconductor material obtainable by the above-described process as a thermoelectric generator or Peltier arrangement.

The present invention further provides thermoelectric generators or Peltier arrangements which comprise the above-described semiconductor material and/or the semiconductor material obtainable by the above-described process.

The present invention further provides a process for producing thermoelectric generators or Peltier arrangements, in which series-connected thermoelectrically active legs with thin layers of the above-described thermoelectric materials are used.

The inventive semiconductor materials can also be combined to thermoelectric generators or Peltier arrangements by methods which are known per se to those skilled in the art and are described, for example, in WO 98/44562, U.S. Pat. No. 5,448,109, EP-A-1 102 334 or U.S. Pat. No. 5,439,528.

The inventive thermoelectric generators or Peltier arrangements widen in a general sense the present range of thermoelectric generators and Peltier arrangements. Variation of the chemical composition of the thermoelectric generators or Peltier arrangements makes it possible to provide different systems which satisfy different requirements in a multitude of possible applications. The inventive thermoelectric generators or Peltier arrangements thus widen the application spectrum of these systems.

The present invention also relates to the use of an inventive thermoelectric generator or of an inventive Peltier arrangement
as a heat pump
for climate control of seating furniture, vehicles and buildings
in refrigerators and (laundry) dryers
for simultaneous heating and cooling of streams in processes for separation such as
   absorption
   drying
   crystallization
   evaporation
   distillation
as a generator for utilization of heat sources such as
   solar energy
   geothermal heat
   heat of combustion of fossil fuels
   waste heat sources in vehicles and stationary units
   heat sinks in the evaporation of liquid substances
   biological heat sources
for cooling electronic components.

The invention also relates to the use of the extruder for reducing the thermal conductivity and for increasing the thermoelectric efficiency of the thermoelectric materials in the extrusion of the thermoelectric materials.

The present invention is illustrated in detail by the example described below.

### EXAMPLE

Extrusion of Lead Telluride

The extrusion was carried out in a batchwise piston extruder. The internal diameter of the extruder was 3.5 cm. A conical narrowing to a diameter of 0.79 cm was achieved through the extrusion die. All operations including the actual extrusion took place under argon as a protective gas.

The starting material, n-lead telluride, was prepared by melt synthesis (mean density: 94.6% of theory) and cut into pieces of from 1 mm to 10 mm in size. These pieces were used directly for extrusion. The extruder was heated to 530° C., and the material was extruded with a pressure of 610 MPa. For the extrusion of 240 g of starting material, about 60 min were required.

What was obtained was a metallically shiny, compact cylindrical shaped body of entirely homogeneous appearance. The density was 99.9% of theory.

The shaped body was cut into slices (thickness 1.5 mm) with a diamond wire saw. In the cross section of the samples, no cracks, holes or cavities whatsoever were observed under the light microscope, nor any inhomogeneities, delimited crystals or discernible particle boundaries.

The thermoelectric characterization gave the measurements shown in FIGS. 1-4 in comparison with the starting material.

Measurements

The Seebeck coefficient is determined by placing the material to be analyzed between a hot contact and a cold contact, the temperature of each being controlled electrically, and the hot contact having a temperature of from 200 to 300° C. The cold side is kept at room temperature, so as to result in a AT of typically from 150 to 280° C. The voltage measured at the particular temperature differential between hot and cold contact provides the Seebeck coefficient specified in each case.

The electrical conductivity is determined at room temperature by a four-point measurement. The process is known to those skilled in the art.

Filled circles=n-PbTe before extrusion

Empty squares=n-PbTe after extrusion

It is clearly evident from the figures that the Seebeck coefficient does not change significantly as a result of the extrusion. The electrical conductivity falls especially for low temperatures. The thermal conductivity is reduced significantly at all temperatures. The thermoelectric efficiency rises significantly, especially for relatively high temperatures.

FIG. 1: Seebeck coefficient as a function of temperature

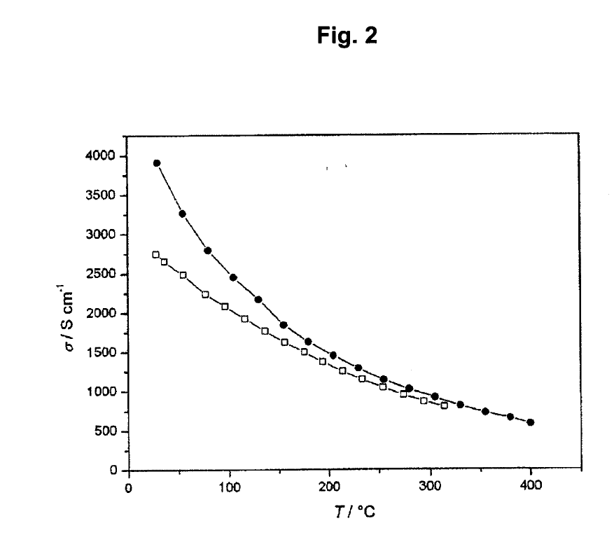

FIG. 2: Electrical conductivity as a function of temperature

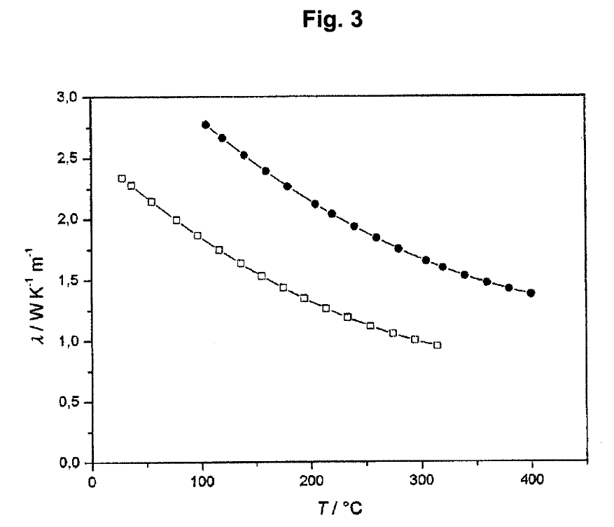

FIG. 3: Thermal conductivity as a function of temperature

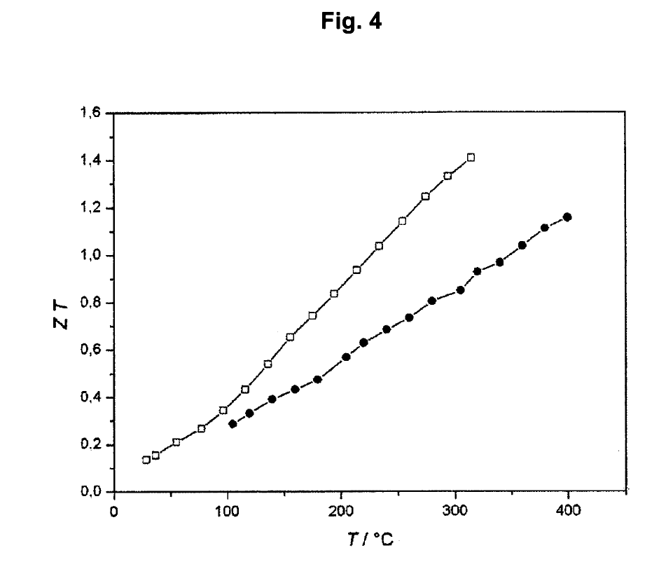

FIG. 4: Thermoelectric efficiency as a function of temperature

1. A process for reducing the thermal conductivity and for increasing the thermoelectric efficiency of at least one thermoelectric material comprising at least one lead chalcogenide, the process comprising extruding the at least one thermoelectric material at a temperature below a melting point of the at least one thermoelectric material and a pressure in the range from 300 to 1000 MPa, wherein the temperature of the extruding is from 500 to 630° C.

2. The process according to claim 1, wherein the temperature of the extruding is from 500 to 560° C.

3. The process according to claim 1, wherein the pressure is from 500 to 700 MPa.

4. The process according to claim 1, wherein the at least one lead chalcogenide is PbTe, which may be n- or p-doped.

5. The process according to claim 1, wherein the extruding is performed as a hot extrusion, hydrostatic extrusion or equal channel extrusion.

6. The process according to claim 1, wherein the at least one thermoelectric material has been prepared by melt synthesis or mixing of element or alloy powders.

7. (canceled)
